(19) United States
(12) Patent Application Publication
(10) Pub. No.: US 2007/0157463 A1
(43) Pub. Date: Jul. 12, 2007

(54) Method for gluing a circuit component to a circuit substrate

(76) Inventors: Willbald Konrath, Weissach im Tal (DE); Haiko Schmelcher, Fichtenberg (DE); Klaus Scholl, Backnang (DE); Ulf Muller, Backnang (DE)

Correspondence Address: COATS & BENNETT, PLLC, 1400 Crescent Green, Suite 300, Cary, NC, 27518, US

(21) Appl. No.: 10/576,639

(22) PCT Filed: Oct. 21, 2004
(86) PCT No.: PCT/EP04/52616

§ 371 Date: Dec. 26, 2006

(30) Foreign Application Priority Data
Oct. 22, 2003 (DE) 10349167.8

(51) Int. Cl. H05K 3/30; B29C 65/00

(52) U.S. Cl. 29/834; 29/832; 29/743; 156/285

(57) ABSTRACT

A circuit component (1) is glued to the circuit substrate (2) by the following steps: a) seizing a circuit component (1) using a grip-per (4); b) moving the gripper (4) towards the surface of the circuit substrate (2) up to a target distance from the surface at which adhesive (3) applied between the circuit component (1) and the circuit substrate (2) is pressed; C) releasing the circuit component (1) and removing the gripper (4) from the circuit component (1); d) turning the gripper (4) around an axis (A) perpendicular to the surface of the circuit substrate (2); e) moving the gripper (4) into the target distance again; and f) removing the gripper (4) again.

The present invention relates to a method for gluing a circuit component to a circuit substrate for the automated assembly of circuits, in particular high frequency circuits.

Generally, soldering or gluing methods are used for fixing a circuit component to a substrate. For an efficient removal of heat from the circuit component into the substrate, an adhesive or solder layer between the two should be as thin as possible and free of voids. For applications in the high-frequency range, in particular for mounting gallium-arsenide-MMICs (Microwave Monolithic Integrated Circuits) it is known to use a eutectic gold-tin-alloy having a thickness of the solder layer of typically 25 mm. The absence of voids can only be guaranteed by checking the solder layer of each soldered circuit component by X-rays. This method is not only laborious to carry out, it also affects the productivity, because circuits where voids have been found in the solder layer must be sorted out and the defective solder layer must eventually be mended afterwards.

In order to achieve as effective a heat transition as in a 25 mm thick solder layer, when using an adhesive such as an epoxy resin loaded with silver flakes to make it electrically conductive, the thickness of the adhesive layer that bonds the circuit component to the circuit substrate must be substantially less than that of a comparable solder layer, since the heat conductivity of the epoxy resin is substantially less than that of a metallic solder. Such a thin adhesive layer cannot be simply produced by spreading adhesive on the circuit substrate or the circuit component and pressing the two together so long or so strongly that the desired thickness of the adhesive layer is achieved. This would cause the adhesive to be squeezed out uncontrollably at the edges of the circuit component, whereby the behaviour of the circuit component might be significantly affected.

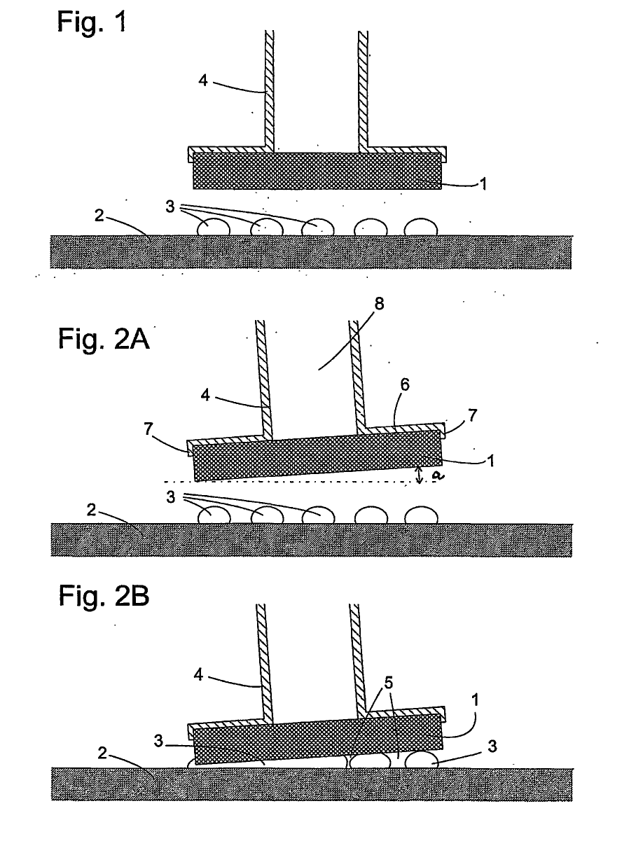

In order to prevent an uncontrolled squeeze-out of the adhesive along the edges of the circuit component and at the same time to ensure that the adhesive layer between the circuit component and the circuit substrate extends up to the edges thereof, the applied adhesive must be metered exactly, e.g. by forming, as shown in FIG. 1, a pattern of adhesive dots 3 of a predefined seize in a specifically predetermined distance on a surface region of the circuit substrate 2 where subsequently a circuit component 1 is to be placed. Here the problem arises that the parallelism between the surface of the circuit substrate 2 and the circuit component which is to be applied to it are the stricter, the less the thickness of the adhesive layer between the component 1 and the substrate 2 is in the finished circuit. If, as shown in FIG. 1, the circuit component 1 is held by a gripper 4 in an ideally parallel configuration to the surface of the circuit substrate and is moved towards the surface of the circuit substrate 2, the circuit component 1 touches all adhesive dots 3 simultaneously and flattens all adhesive dots 3 to the same degree, so that the air between the circuit component 1 and the circuit substrate 2 is displaced and the adhesive dots 3 merge into a continuous layer of the desired thickness.

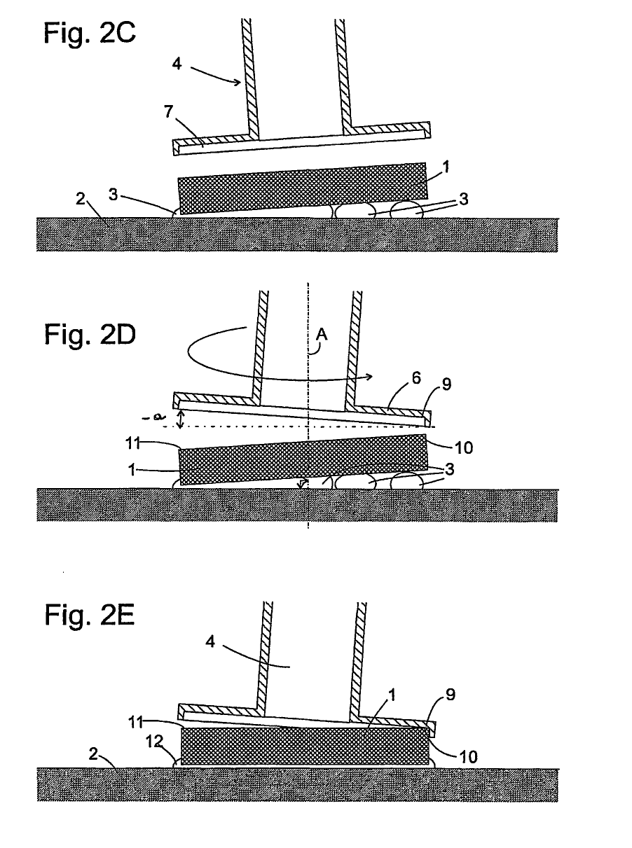

In practice, ideal parallelism between the surfaces of the circuit component 1 and the circuit substrate 2, which are to be fixed to each other, is never exactly achieved. Under realistic application conditions, the facing surfaces of the circuit substrate 2 and circuit component 1 held by a gripper 4 form a small acute angle a, as shown in FIG. 2A. When the gripper 4 holding the circuit component 1 is moved towards the circuit substrate 2, this causes a lateral region of the circuit component 1, the left lateral region in FIG. 2B, to come into contact with the adhesive dots 3 first and to flatten these before the right side of the circuit component 1 comes into contact with the adhesive dots. If the adhesive cures in this form, voids 5 remain between the circuit component 1 and the circuit substrate. This causes a non-uniform heat removal from the circuit component 1 into the substrate 2, whereby overheating of the circuit component 1 may be caused in regions that are separated from substrate 2 by a thick adhesive layer with voids therein. Further, different regions. of the circuit component 1 see different effective dielectric constants in their surroundings, which may cause locally varying attenuations, in particular in high frequency applications, and hence, irreproducible behaviour of the mounted circuit component 1.

One approach to this problem is to pose very strict requirements concerning the orientation of the gripper 4 with respect to the surface of the circuit substrate 2 in order to make the parallelism error between the facing circuits of circuit substrate 2 and circuit component 1 small. Such strict requirements for the gripper and its driving mechanism cause high costs and still provide no final solution of the problem. In order to exclude that a parallelism error between the circuit component and the circuit substrate causes voids to remain in the adhesive layer between the two, it must be ensured that the difference between the distances of opposite edges of the circuit component from the circuit substrate does not exceed a certain limit, which depends on the desired thickness of the adhesive layer. The greater the distance between the concerned edges of the circuit component is, the smaller must the maximum admissible parallelism error be made in order to prevent formation of voids. i.e. the larger the circuit components become, the more difficult it is to place them so exactly parallel that no voids in the adhesive layer remain.

The object of the present invention is to provide a method for gluing a circuit component to a circuit substrate which allows to ensure a constant thickness of the adhesive layer over the whole area of a circuit component to be glued and, thus, the absence of voids in the adhesive layer, without a need for extremely high requirements for the guiding mechanism of a gripper which is used for placing the circuit component on a circuit substrate.

The object is achieved by a method having the features of claim 1.

The first steps of this method, namely seizing the circuit component using the gripper, approaching the gripper to the surface of the circuit substrate up to a predetermined target distance from the surface which is predetermined dependent on a desired thickness of the adhesive layer and releasing the circuit component and removing the gripper are similar to the initially described conventional procedure. After these first steps, it is not excluded that due to the unavoidable parallelism error between the circuit component and the circuit substrate voids remain in part of the adhesive layer. In order to remove these, according to the invention, the steps of turning the gripper around an axis perpendicular to the surface of the circuit substrate, moving the gripper into the target distance again and removing the gripper again, are provided. In this way, when the gripper is moved into the target distance for the second time, a region of the circuit component under which the adhesive layer is still rather thick and may contain voids is pressed by a part of the gripper which, when moved towards the circuit substrate for the first time, has pressed a region of the circuit component close to the circuit substrate, and is thus pressed close to the circuit substrate, too. In this way, distances of opposite edges of the circuit component from the circuit substrate are made identical independently of the dimensions of the circuit component, and even below a region of the circuit component which after the first pressing step is still rather far away from the circuit component, residual air is expelled from between the circuit component and the circuit substrate, so that an adhesive layer without voids is formed.

When moving the gripper towards the surface of the circuit substrate for the first time, the target distance is preferably deemed reached when a force resulting from the deformation of the adhesive and opposed to the movement of the gripper has reached a predefined value. In this way, it is guaranteed that even if the level of the surface on which the circuit component is glued differs slightly from one gluing procedure to the other, the adhesive layer is compressed to the necessary extent in every case.

Since the adhesive layer is already deformed when the gripper is moved towards the circuit substrate for the second time, the opposing force can no longer be used as a criterion for whether the target distance is reached. Therefore, during the first movement preferably a local coordinate value of the gripper is detected at which the target distance is deemed reached, and the second movement is performed up to this same coordinate value.

The angle by which the gripper is rotated between the first and second movements should generally be 180°, but other values may be considered if the circuit component to be glued has an odd-numbered symmetry.

In order achieve a heat conductivity value comparable to that of a metallic solder layer between the circuit component and the circuit substrate, the adhesive layer should be metered such that it yields a thickness of less than 10 mm, preferably approx. 5 mm.

Such an adhesive layer may be applied in advance as a regular pattern of adhesive dots on the circuit substrate using a dispenser.

In order to ensure that the adhesive layer fills the space between the circuit component and the circuit substrate completely, up to the corners of the circuit component, it is useful to apply additionally individual adhesive dots which are closer to a corner of the circuit component than the dots of the pattern and which thus promote the progress of the adhesive into the corners when pressing the circuit component.

For generating a void-free adhesive layer, it is also advantageous if an additional adhesive dot or a row of additional adhesive dots is applied approximately centrally in the area of the regular pattern.

For carrying out the method, a gripper is particularly appropriate which has an abutment surface that abuts against at least two opposite edges of a surface of a seized circuit component, which is remote from the circuit substrate.

It is also advantageous to use a gripper in which for seizing and releasing the circuit component no parts that touch the circuit component must be moved, in particular a pneumatic gripper wherein for seizing a circuit component a suction opening of the gripper is placed over the circuit component and the circuit component is sucked.

Further features and advantages of the invention become apparent from the subsequent description of an embodiment referring to the appended drawings.

FIG. 1, already discussed, shows a gripper with a circuit component held ideally parallel to a support surface;

FIGS. 2A, 2B, already discussed, illustrate stages of a conventional method for gluing a circuit component to a circuit support, in which the circuit component is not held ideally parallel to the circuit support;

FIGS. 2C to 2E illustrate stages of the gluing method of the invention;

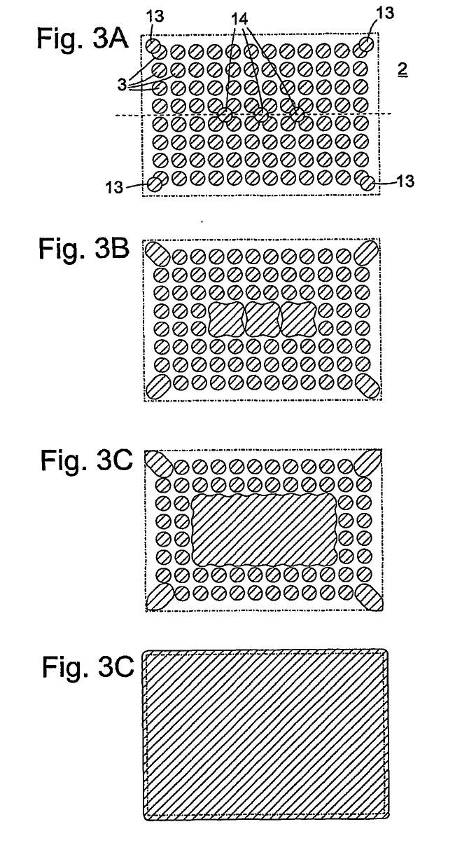

FIG. 3A shows a distribution of adhesive dots on a circuit substrate before placing a circuit component; and

FIGS. 3B to 3D show sections through the adhesive layer while pressing a circuit component against the circuit substrate and after pressing, respectively.

In the first stage of the method of the invention shown in FIG. 2A, in a region of circuit substrate 2 where a circuit component 1 is to be glued, a regular pattern of adhesive dots 3 and some additional dots, not shown in FIG. 2A, are applied, the function and arrangement of which is explained in detail referring to FIG. 3A. The size of the adhesive dots 3 of the pattern and their distance from each other are selected such that the dots 3, when compressed between the circuit substrate 2 and the circuit component 1, form a void-free adhesive layer of approximately 5 mm thickness.

In a distance from the adhesive dots 3, the circuit component 1 to be glued is shown, held by a gripper 4. The gripper 4 has an abutment surface 6 where the upper side of the circuit component 1 abuts and which, due to unavoidable mechanical inaccuracies, is tilted with respect to the horizontal by a small angle a which is shown grossly exaggerated in the Figure. The surface of the circuit substrate 2 is assumed to be oriented exactly horizontally.

The abutment surface 6 is surrounded by a continuous rib 7, which is adapted to the dimensions of the circuit component 1 and is in contact with the lateral flanks thereof. In this way, the position of the circuit component at the gripper is unambiguously defined, and the circuit component can be placed reproducibly without therefore having to detect its position at the gripper. A suction collar 8, which extends from the abutment surface, 6 has a negative pressure applied to it by a suction pump, whereby the circuit component 1 is held at the gripper 4.

If various components of different shape are to be placed using a same gripper, instead of the gripper 4 with the continuous rib 7, a gripper, not shown, may be used which has a suction bell, the narrow edge of which is pressed against a planar surface of a component to be seized, so that the edges of the planar surface extend beyond the edges of the suction bell. Such a gripper is not limited to a certain shape of the component, however, in that case the position of a seized component at the gripper should be detected in order to be able to control the gripper so that it reproducibly places the component at a desired location of the circuit substrate.

The gripper 4 is moved towards the surface of the circuit component 1 while continuously measuring a counteracting force, which opposes the downward movement. Such a force occurs as soon as the circuit component 1 touches the adhesive dots 3 and begins to deform these. When the counteracting force reaches a limit which has been appropriately determined empirically in advance and which indicates a sufficient deformation of the adhesive dots 3, a height coordinate value of the gripper 4, i.e. a value of a coordinate in the direction perpendicular to the surface of the circuit substrate 2, is detected. It is not necessary to calibrate a path sensor coupled to the gripper 4 which is used to this effect.

FIG. 2B shows the gripper 4 with the circuit component 1 in the thus defined target distance. Underneath part of the circuit component 1, here the left hand half thereof, the adhesive dots 3 are merged into a continuous layer; elsewhere, voids 5 between the circuit component 1 and the circuit substrate 2 may still exist. In order to release the circuit component 1, the negative pressure at the suction collar 8 of the gripper 4 is removed and, if necessary, a slight positive pressure is generated. The gripper 4 is raised as shown in FIG. 2C and then turned by 180° around an axis A perpendicular to the surface of the circuit substrate 2 into the position shown in FIG. 2D. The gripper is now tilted by an angle −a against the horizontal, i.e. an edge 9 of the abutment surface 6 which is rather close to the surface of the circuit substrate 2 now faces an edge 10 of the circuit component 1 which is rather far away from this surface.

If afterwards, as shown in FIG. 2E, the gripper 4 is descended exactly to the target height detected by the path sensor in the stage of FIG. 2B, the edge 9 of the abutment surface 6 presses the edge 10 of the circuit component just as close to the surface of the circuit substrate as it did before to the opposite edge 11. The adhesive between the circuit component 1 and the circuit substrate 2 now forms a continuous, void-free layer 12 between the circuit component 1 and the circuit substrate 2.

In general, pressing twice as described above is sufficient to achieve a highly uniform thickness of the adhesive layer 3 on the whole gluing area between the circuit component 1 and the circuit substrate 2. In case of need, turning and pressing the gripper 4 may be repeated several times.

In particular, while pressing for the second time, the counteracting force occurring up to when the target heat is reached may be detected, and if it exceeds a given percentage of the limit value of the counteracting force used for defining the target height when pressing for the first time, the gripper is again turned by 180° and moved to the target height in order to press once more.

FIG. 3A is a top view of the surface of the circuit substrate 2 with a pattern of adhesive dots 3 formed thereon. The outline of a circuit component 1 to be placed is shown as a dash-dot rectangle. Inside the rectangle, the adhesive dots 3 form a regular rectangular pattern of lines and columns, and over each dot 3 at a corner of the row-column pattern, an additional dot 13 is applied, displaced towards the corner of the circuit component 1. Further additional dots 14, three dots in the present case, are placed along a longitudinal centre line of the circuit component 1.

When it is begun to press the circuit component 1 against the circuit substrate 2 and thereby to squeeze the adhesive dots flat, at first the additional dots 13, 14 begin to merge with adjacent dots 3 of the regular pattern and to spread, as shown in FIG. 3B. Larger continuous adhesive areas are thus formed at first in the centre of the pat-tern, and the dots 13 spread towards the corners of the circuit component 1. The more the circuit component 1 approaches the substrate, the more the continuous adhesive area spreads from the centre and engulfs one ring of dots 3 after the other, while continuously expelling air from the spaces between the dots 3, as shown in FIG. 3C. Finally, as shown in FIG. 3D, a continuous, void-free adhesive layer 12 is obtained which extends over the complete bottom side of the circuit component 1 and projects slightly beyond its edges, the extent of the projection being controllable by metering the applied quantity of adhesive and the thickness of the adhesive layer, i.e. by the limit value of the force where the target distance is deemed reached.

1-10. (canceled)

11. A method for gluing a circuit component to a circuit substrate comprising:
seizing a circuit component using a gripper;
moving the gripper towards a surface of the circuit substrate a first time to a target distance from the surface at which adhesive applied between the circuit component and the circuit substrate is pressed;
releasing the circuit component and removing the gripper from the circuit component;
turning the gripper around an axis perpendicular to the surface of the circuit substrate;
moving the gripper to the target distance a second time; and
removing the gripper.

12. The method of claim 11 further comprising when moving the gripper toward the substrate the first time, detecting a counteracting force opposing the movement of the gripper and defining the target distance to be the distance at which the opposing force reaches a predetermined value.

13. The method of claim 12 further comprising detecting a local coordinate of the target distance the first time and wherein moving the gripper into the target distance a second time comprises moving the gripper to the detected local coordinate.

14. The method of claim 11 wherein turning the gripper around an axis perpendicular to the surface of the circuit substrate comprises turning the gripper through a turning angle of approximately 180 degrees.

15. The method of claim 11 further comprising metering the adhesive to yield an adhesive layer of less than 10 mm thickness.

16. The method of claim 15 wherein the adhesive layer is approximately 5 mm thick.

17. The method of claim 11 further comprising applying the adhesive in advance to the circuit substrate as a regular pattern of adhesive dots.

18. The method of claim 17 further comprising applying additional individual adhesive dots closer to a corner of the circuit component than the dots of the regular pattern of adhesive dots.

19. The method of claim 17 further comprising applying one or more additional dots to a central area of the regular pattern.

20. The method of claim 11 wherein the gripper includes an abutment surface that abuts against at least two opposite edges of a surface of the circuit component that faces away from the circuit substrate.

21. The method of claim 11 wherein seizing a circuit component using a gripper comprises placing a suction opening of the gripper over the circuit component to be seized, and creating a vacuum between the suction opening and the circuit component.
